(19) United States
(12) Patent Application Publication
(10) Pub. No.: US 2009/0079074 A1
(43) Pub. Date: Mar. 26, 2009

(54) Semiconductor device having decoupling capacitor formed on substrate where semiconductor chip is mounted

(75) Inventor: Kazuhiro Motonaga, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/232,008

(22) Filed: Sep. 9, 2008

(30) Foreign Application Priority Data
Sep. 25, 2007 (JP) 2007-246640

(51) Int. Cl. H01L 23/498

(52) U.S. Cl. 257/738; 257/E23.069

(57) ABSTRACT

A semiconductor device includes a substrate having a first surface and a second surface opposing to the first surface, a semiconductor chip mounted on the first surface of the substrate, a first pad formed on the first surface of the substrate to electrically connect to a first terminal of the semiconductor chip, a second pad formed on the second surface of the substrate to electrically connect to a second terminal of the semiconductor chip, and a decoupling capacitor formed on the first surface and including the first and second pads serving as electrodes of the decoupling capacitor.

### BACKGROUND OF THE INVENTION

1. Field of the Invention

The present invention relates to a semiconductor device including a decoupling capacitor, and more specifically, to a ball grid array (BGA) type semiconductor device including solder balls connected to external devices on the back side of a substrate.

2. Description of Related Art

Where a semiconductor chip performs a high speed operation, the semiconductor chip consumes a large current. A voltage drop of a power supply voltage is caused due to such a large current consumption. This voltage drop degrades the performance of a semiconductor device. For this reason, a decoupling capacitor, for example, is formed to prevent a rapid fluctuation in a power supply voltage. The decoupling capacitor stores electric charge and helps to supply electricity from the power supply voltage. Thereby, the voltage drop of the power supply voltage is suppressed.

FIGS. 7 and 8 show a semiconductor device having a decoupling capacitor formed therein of a related art. In a semiconductor device shown in FIG. 7, a semiconductor chip 92 is mounted on a multilayer substrate 91. A plurality of ground pads 93a, power-supply pads 93b, and signal pads 93c for inputting and outputting signals are formed on the substrate 91. Each ground pad 93a is connected to some one of solder balls 94 formed on the back side of the substrate 91 via a corresponding some one of through holes 91a formed in the substrate 91. Then, a ground voltage is supplied to the ground pads 93a from a ground voltage supply section (not shown) connected to the solder balls 94. Moreover, each power supply pad 93b is connected to some one of the solder balls 94 formed on the back side of the substrate 91 via a corresponding some one of the through holes 91a formed in the substrate 91. Then, a power supply voltage is supplied to the power supply pads 93b from a power voltage supply section (not shown) connected to the solder balls 94. Furthermore, capacitance components to function as decoupling capacitors 95 are formed on the back side of the substrate 91. In the capacitance components, a dielectric film is formed between opposing electrodes. Here, current supply paths from the capacitance components to the semiconductor chip 92 are indicated by double-dashed lines and dashed lines. In addition, the semiconductor chip 92 is connected to the ground pads 93a and to the power supply pads 93b by bonding wires 96. Additionally, a mold resin 97 is formed for preventing a disconnection of the bonding wires 96 or the like.

In the semiconductor device shown in FIG. 7, the capacitance components, as the decoupling capacitors 95, are formed on the back side of the substrate. Accordingly, the semiconductor chip 92 and the decoupling capacitors 95 are placed apart from each other. When the distance between the semiconductor chip 92 and the decoupling capacitors 95 is long, a response speed of supplying voltage from decoupling capacitors 95 to the semiconductor device 92 is low. Further, when the decoupling capacitors are formed on the back side of the substrate, and if the solder balls 94 formed on the back side of the substrate are not high enough, the substrate 91 may tilt due to the thickness of the decoupling capacitors 95. Instead, in a semiconductor device shown in FIG. 8, capacitance components as decoupling capacitors 95 are formed inside a multilayer substrate 91. In this case, the distance between the semiconductor chip 92 and the capacitance components is short, compared with the semiconductor device shown in FIG. 7. However, the response speed of supplying voltage from the capacitance components to the semiconductor device 92 is still not high enough. Moreover, the semiconductor device is needed to be formed by using a multilayer substrate.

To address the above problems, Japanese Laid Open Patent Application No. Hei 7-297316 (hereafter “Document”) discloses a semiconductor device having capacitance components as decoupling capacitors formed on the same side of the substrate where a semiconductor chip is mounted. The capacitance components are formed on a metal film which is formed on the substrate. The metal film is connected, via wires, to a lead frame which is connected to the outside of the semiconductor device. The lead frame is connected to the semiconductor chip via the wires. Since the capacitance components are formed on the substrate in this semiconductor device, the physical distance between the semiconductor chip and the capacitance components is short, compared with the semiconductor shown in FIG. 8. Thereby, the response speed from the capacitance components to the semiconductor chip can be improved. Further, instead of a semiconductor device with capacitance components having a dielectric film formed between opposing electrodes, the Document discloses a semiconductor device in which capacitances are each formed by using an electrode and a dielectric film that are formed on a substrate.

In the semiconductor device, described in the Document, in which the capacitances are each formed of the electrode and the dielectric film, a first metal film as a ground layer is formed on the substrate. A dielectric layer is formed on the first metal film, and a second metal film as a power supply layer is formed on the dielectric layer. The second metal film is connected, via wires, to a lead frame which is to be connected to external devices, and the lead frame is connected to the semiconductor chip via the wires. In this way, the first metal film, the dielectric layer and the second metal film collectively form a capacitance.

### SUMMARY OF THE INVENTION

However, in the semiconductor device, described in the Document, in which capacitance components are formed on a substrate, the capacitance components are formed as decoupling capacitors, and therefore, the layout of the semiconductor device needs to be designed in accordance with the shapes of the capacitance components. For this reason, the manufacturing processes for the semiconductor device are complicated. In the semiconductor device, described in the Document, in which the capacitances are each formed of an electrode and a dielectric film, a second metal film having a predetermined area is formed as one of the electrodes of the capacitance. Accordingly, the second metal film as the one of the electrodes of the capacitance and the semiconductor chip are connected via a plurality of wires and lead frames. The electrical distance between the semiconductor chip and the capacitance is therefore long, thus leading to a problem that a response speed of supplying voltage from the capacitance to the semiconductor chip is low. A possible way to solve the problem is to remove the wires, which connect the lead frame and the second metal film, and the second metal film, and to cause the lead frame to serve as one of the electrodes of the capacitance, so that the lead frame, now acting as one of the electrodes of the capacitance, is connected to the semiconductor chip. But, in this case, it is difficult to form a capacitance having a large capacitance value because a lead frame with a small area serves as one of the electrodes of the capacitance.

A semiconductor device according to an exemplary aspect of the present invention includes a substrate having a first surface and a second surface opposing to the first surface, a semiconductor chip mounted on the first surface of the substrate, a first pad formed on the first surface of the substrate to electrically connect to a first terminal of the semiconductor chip, a second pad formed on the second surface of the substrate to electrically connect to a second terminal of the semiconductor chip, and a capacitor formed on the first surface and including the first and second pads as electrodes of the decoupling capacitor and a dielectric film formed between the first and second pads.

In the present invention, the capacitance is formed of the first pad and the second pad formed on the substrate, and the dielectric film formed between the first pad and the second pad. Accordingly, the capacitance can be formed near the semiconductor chip, so that the electrical distance between the semiconductor chip and the capacitance can be shortened.

With a semiconductor device according to the present invention, a response speed of the voltage supply from a capacitance to a semiconductor chip can be improved.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a cross-sectional view showing a semiconductor device according to a first exemplary embodiment;

FIG. 2 is a plan view showing a manufacturing process of the semiconductor device according to the first exemplary embodiment;

FIG. 3 is a plan view showing the manufacturing process of the semiconductor device according to the first exemplary embodiment;

FIG. 4 is a plan view showing the manufacturing process of the semiconductor device according to the first exemplary embodiment;

FIG. 5 is a plan view showing the semiconductor device according to the first exemplary embodiment with a forming region of an electrode 7 indicated by dotted lines;

FIG. 6 is a plan view showing a back side of the semiconductor device according to the first exemplary embodiment;

FIG. 7 is a cross-sectional view showing a semiconductor device having capacitance components formed on the back side of a substrate of a related art; and

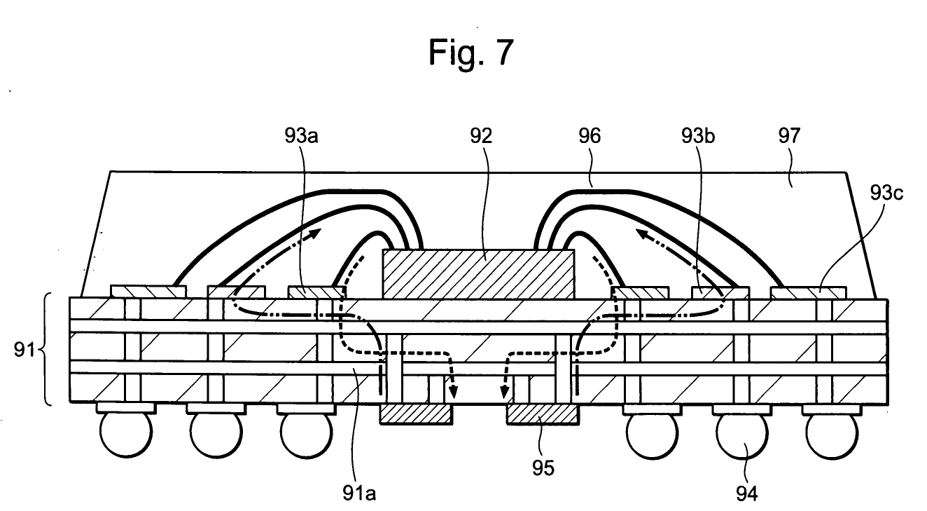

FIG. 8 is a cross-sectional view showing a semiconductor device having capacitance components formed inside a substrate of a related art.

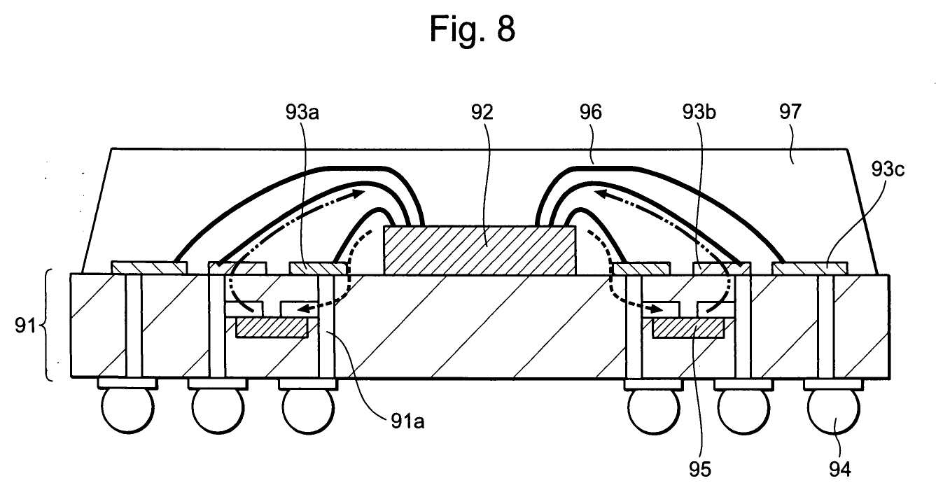

### DETAILED DESCRIPTION OF THE EXEMPLARY EMBODIMENTS

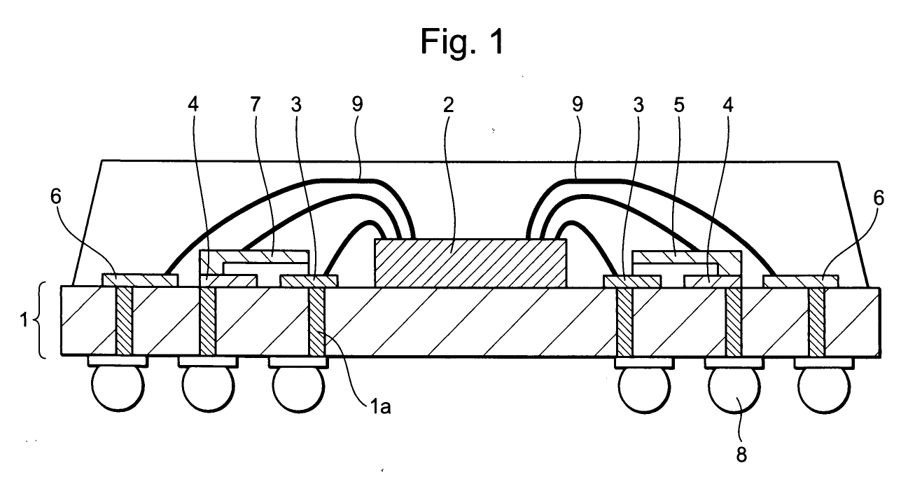

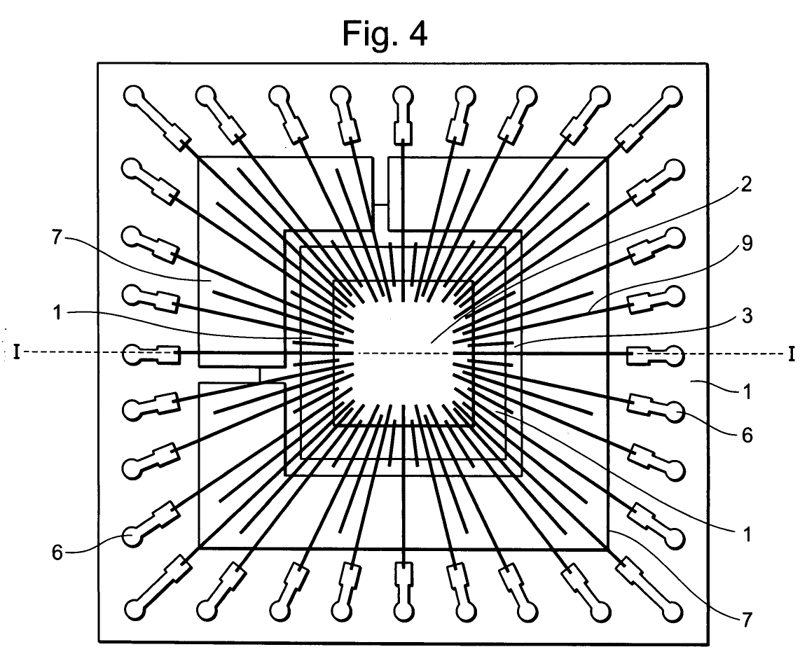

FIG. 1 shows a cross-sectional view of a semiconductor device according to an exemplary embodiment of the present invention. This exemplary embodiment applies the present invention to a BGA type semiconductor device having a plurality of solder balls formed on the back side of a substrate so as to connect the semiconductor device to external devices. Note that FIG. 1 is a cross sectional view taken along the line I-I in FIG. 4, which will be described later.

As shown in FIG. 1, the semiconductor device according to the present exemplary embodiment includes an insulating substrate 1. Formed on the substrate 1 are a semiconductor chip 2, a first pad 3, a second pad 4, a dielectric film 5, and signal pads 6 as a third pad. Further, an electrode 7 is formed on the second pad 4 and the dielectric film 5. Additionally, solder balls 8 are formed on the back side of the substrate 1. Moreover, the semiconductor chip 2 is connected respectively to the first pad 3, to the electrode 7 formed on the second pad 4, and to the signal pads 6, via a bonding wire 9. Furthermore, a mold resin 10 covering the semiconductor chip 2 and the bonding wires 9 is formed to prevent a disconnection of bonding wires 9 and so on.

Next, the semiconductor device according to the present exemplary embodiment will be described in more detail. Multiple through holes I a are formed in the substrate 1. Via the through holes 1a, the first pad 3, the second pad 4, and the signal pads 6 are connected to the respective solder balls 8 formed on the back side of the substrate. The first pad 3 is formed over the through hole 1a and is a ground pad set at a ground potential. The first pad 3 applies the ground potential to the semiconductor chip 2. The second pad 4 is formed over the through holes 1a and is a power supply pad which supplies a power supply voltage to the semiconductor chip 2. The dielectric film 5 is formed between the first pad 3 and the second pad 4.

Further, in the present embodiment, the dielectric film 5 is formed to cover a part of the first pad 3 and a part of the second pad 4. The electrode 7 is formed on the second pad 4 and the dielectric film 5. That is, the electrode 7 is connected to the second pad 4 and disposed above the first pad 3 so as to overlap a part thereof. Here, the electrode 7 is connected to the second pad 4 and disposed to be overlapped with the first pad 3. Alternatively, the electrode 7 may be connected to the first pad 3 and disposed to be overlapped with the second pad 4. A capacitance is formed of the first pad 3, the second pad 4 and the electrode 7, as well as the dielectric film 5. That is, the second pad 4 and the electrode 7 function as one side of the electrodes of the capacitance, and the first pad 3 functions as the other side of the electrodes.

Each signal pad 6 is formed over the through hole 1a and connected to a signal terminal included in the semiconductor chip 2. Signals, between the semiconductor chip 2 and external devices or the like connected to the outside of the semiconductor device, are sent and received via the signal pads 6. Some ones of the solder balls 8 are connected to a ground voltage supply section (not shown) which applies a ground potential, while another one is connected to a power supply voltage section (not shown) which supplies power supply voltage.

Then, through these solder balls 8, the ground voltage supplied from the ground voltage supply section is supplied to the first pad 3 via the corresponding through hole 1a, while the power supply voltage supplied from the power supply voltage section is supplied to the second pad 4 via the corresponding through hole 1a. That is, the solder balls 8 electrically connect the first pad 3 and the second pad 4 to the external devices via the through holes 1a formed in the substrate 1.

In the present exemplary embodiment, the dielectric film 5 is formed to cover a part of the first pad 3 and a part of the second pad 4 so as to form a capacitance with larger capacitance value. The dielectric film 5, which is formed on the first pad 3 and the second pad 4, is preferred to be thinner so as to enlarge the capacitance value. In addition, for example, the electrode 7 is formed on the second pad 4 and the dielectric film 5. That is, the electrode 7 and the second pad 4 serve as one side of the electrodes of the capacitance. The first pad 3, the second pad 4 and the electrode 7, as well as the dielectric film 5 collectively form the capacitance.

Moreover, the electrode 7 to serve as one side of electrodes of the capacitance and the first pad 3 are connected to the semiconductor chip 2 respectively by the bonding wire 9. That is, by forming the capacitance with the first pad 3, the second pad 4 and the electrode 7, as well as the dielectric film, which are formed near the semiconductor chip 2, the capacitance can be formed near the semiconductor chip 2. This shortens the electrical distance between the semiconductor chip 2 and the capacitance, thereby improving the response speed of supplying voltage from the capacitance to the semiconductor chip 2. In addition, a wiring length between the semiconductor chip 2 and the capacitance can be shortened. As a result, an interconnect resistance and inductance are reduced, to thereby reduce noise generation.

In the case of the related art, the semiconductor chip is connected to the capacitance section via a wire lead frame and wires. In the present exemplary embodiment, on the other hand, the semiconductor chip and the capacitance section can be connected to each other via only wires. Therefore, the physical distance between the semiconductor chip and the capacitance section can be reduced to about one fifth of the distance though it depends on the size of the semiconductor device. For example, about a several 100 mΩ resistance can be reduced to about 100 mΩ, and about 10 nH (nano Henry) inductance can be reduced to about 1 to 2 nH.

Further, in the present exemplary embodiments, by forming the dielectric film 5 formed on the first pad 3 and the second pad 4 to be thin, the capacitance with larger capacitance value can be formed. In the present embodiment, with the electrode 7 formed on the second pad 4 and the dielectric film 5 serving as one side of the electrodes of the capacitance, the first pad 3, the second pad 4 and the electrode 7, as well as the dielectric film 5 collectively form the capacitance. Alternatively, the electrode 7 may be formed on the first pad 3 and the dielectric film 5, and the first pad 3 and the electrode 7, the pad 4, as well as the dielectric film may collectively form the capacitance.

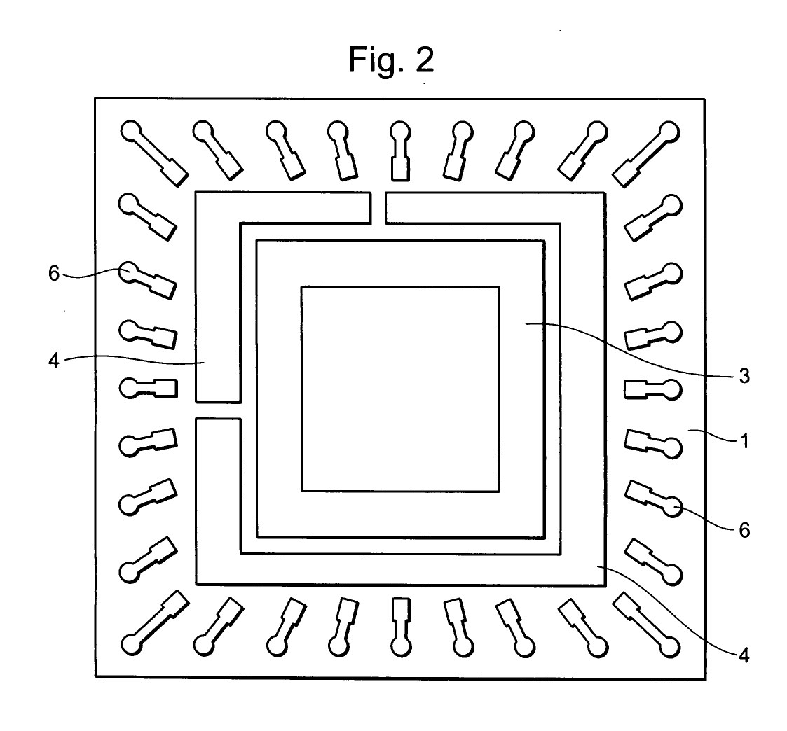

Here, a method for manufacturing the semiconductor device according to the present exemplary embodiment will be explained briefly with reference with FIGS. 2 to 5 showing plan views of the semiconductor device.

At first, as shown in FIG. 2, the first pad 3, the second pad 4, and the signal pads 6 are formed on the substrate 1. Multiple first pad 3 and multiple second pad 4 may be formed. In this case, with the signal pads 6 disposed at the periphery of the substrate 1, at least one of the first pad 3 and the second pad 4 may be disposed, on the substrate 1, just inside the inner end of the signal pads 6. In addition, the first pad 3 and the second pad 4 may be disposed on the outside of the signal pads 6 on the substrate 1.

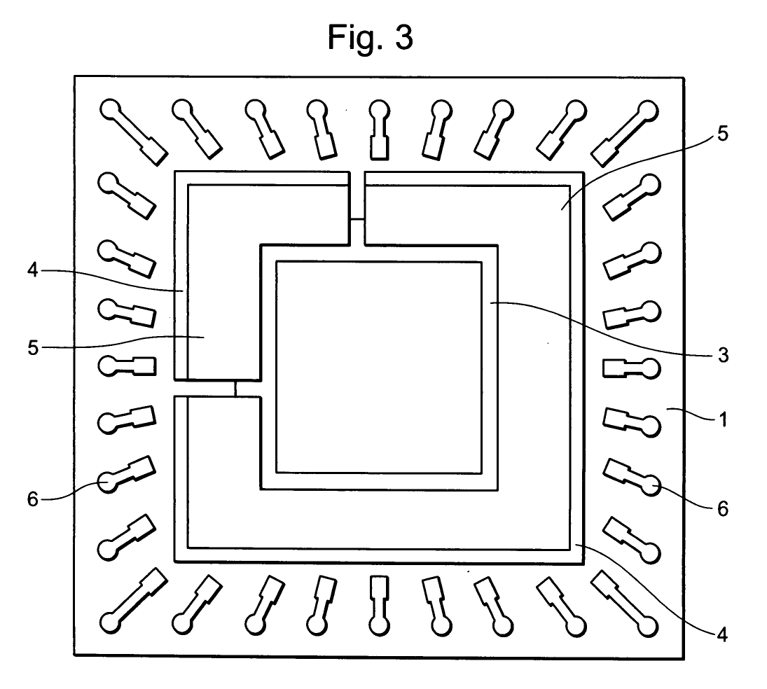

Next, as shown in FIG. 3, the dielectric film 5 is formed to cover a part of the first pad 3 and a part of the second pad 4. Then, as shown in FIG. 4, the electrode 7 is formed on the dielectric film 5 and the second pad 4. Moreover, the semiconductor chip 2 is formed at a desired position of the substrate 1. The semiconductor chip 2 is connected to the substrate 1 by using, for example, bonding wires. Otherwise, the semiconductor chip 2 is flip-chip connected to the substrate 1 by using bumps. Then, the semiconductor chip 2 is connected respectively with the first pad 3, the electrode 7, and the signal pads 6 by bonding wires 9. After that, the mold resin 10 (not shown) is formed.

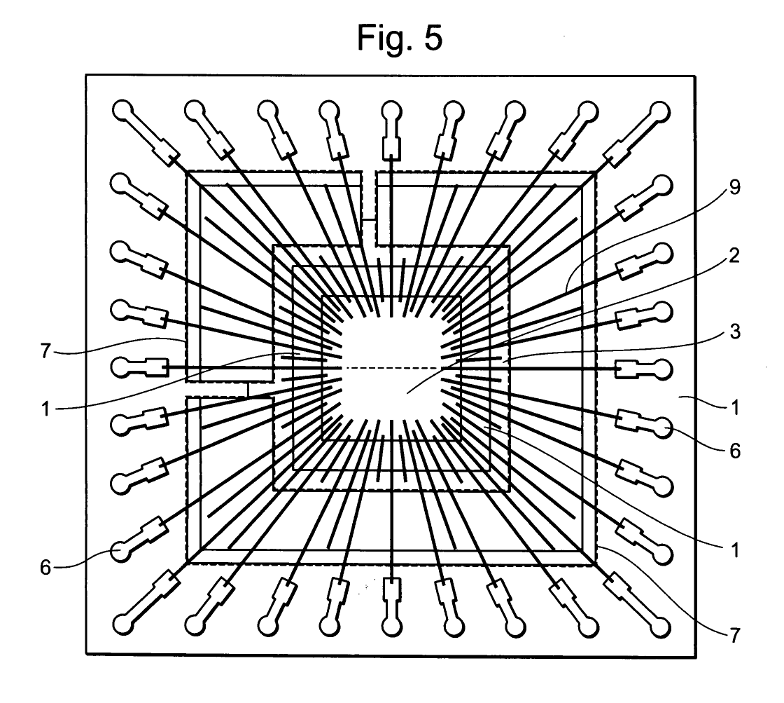

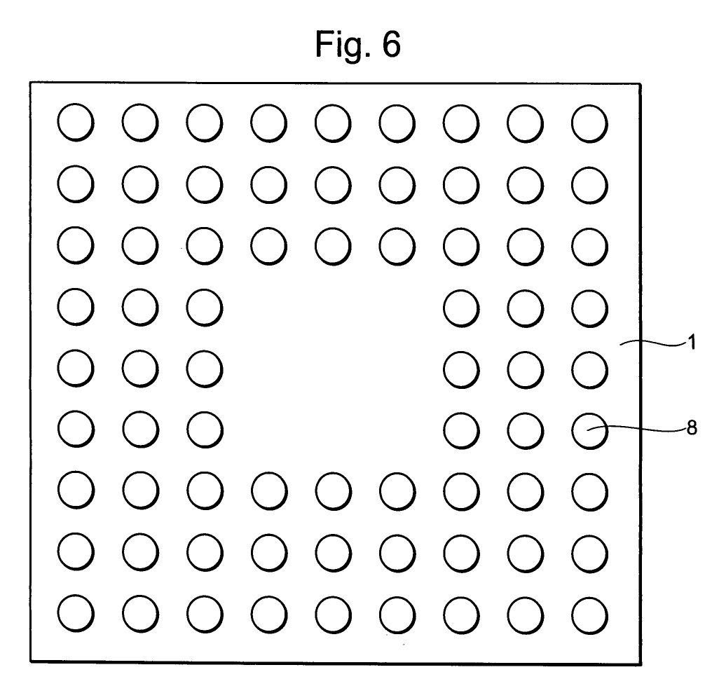

Here, FIG. 5 corresponds to the semiconductor device shown in FIG. 4 and clearly shows a forming region of an electrode 7. In FIG. 5, the forming region is indicated by dotted lines. As shown in FIG. 5, the electrode 7 is formed on the dielectric film 5 and the second pad 4. Referring back to FIG. 4, after the formation of the mold resin (not shown), the solder balls 8 are formed on the back side of the substrate 1. FIG. 6 shows a plan view of the back side of the substrate according to the present exemplary embodiment. As shown in FIG. 6, the substrate I includes the plurality of through holes 1a. The solder balls 8 are formed on the back side of the substrate 1 so as to be connected to the first pad 3, the second pad 4, and the signal pads 6, each of which are formed over the corresponding through hole 1a. In this way, the semiconductor device is formed.

In the present exemplary embodiment, the first pad 3, the electrode 7 and the second pad 4, as well as the dielectric film 5 collectively form the capacitance. This capacitance functions as a decoupling capacitor. That is, the first pad 3 serves as one side of the electrodes of the capacitance, while the second pad 4 and the electrode 7 serve as the other side of the electrodes of the capacitance, all of which are formed near the semiconductor chip 2. For that reason, the capacitance as a decoupling capacitor can be formed near the semiconductor chip 2, thereby shortening the electrical distance between the capacitance and the semiconductor chip 2. As a consequence, the response speed of voltage supply from the capacitance to the semiconductor chip 2 can be improved. In addition, a wiring length between the semiconductor chip 2 and the capacitance can be shortened, so that an interconnect resistance and inductance can be reduced, to thereby reduce noise generation.

It should be noted that, although the dielectric film 5 is formed to cover a part of the first pad 3 and a part the second pad 4 which are formed on the substrate 1 in the present embodiment, the dielectric film 5 may alternatively be formed, for example, just between the first pad 3 and the second pad 4. When the dielectric film 5 is formed just between the first pad 3 and the second pad 4, the forming area of the dielectric film 5 is small. Accordingly, the capacitance value of the capacitance formed of the first pad 3, the second pad 4, and the dielectric film 5 is considered to be low. However, a dielectric film with high dielectric constant has been developed recently, so when the dielectric film with high dielectric constant is used as a dielectric film to form a capacitance, the capacitance having a large capacitance value can be formed even if the forming area of the dielectric film is small. Therefore, the dielectric film 5 may be formed just between the first pad 3 and the second pad 4.

Additionally, the first pad 3 and the second pad 4 of the semiconductor device according to the present exemplary embodiment are connected to the solder balls 8 via the plurality of through holes 1a formed in the substrate 1. The solder balls 8 can be formed to be close to each other on the whole surface of the back side of the substrate 1. Thus, a large amount of data can be sent and received between the semiconductor chip 2 and the external devices of the semiconductor device through signals sent and received therebetween.

Moreover, the semiconductor device according to the present exemplary embodiment includes no capacitance component. Therefore, there is no need to design the layout of the substrate in consideration of the space for mounting the capacitance components therein. Also, a reflow process for pre-coating the solder and forming the capacitance components on the pre-coated solder is not needed, which process would be required when the capacitance components is mounted. Therefore, since the first pad 3, the second pad 4, and the dielectric film 5 form the capacitance on the substrate 1, it is possible to change the capacitance value freely, compared with the case of forming the capacitance components inside the substrate 1.

It should be noted that the present invention is not limited to the above mentioned exemplary embodiments, and various modifications are possible within the scope of the present invention. For example, a plurality of dielectric films with different dielectric constants may be used as the dielectric film 5, so as to form a plurality of capacitances with different capacitance values. Further, although the semiconductor device according to the present exemplary embodiment uses a bilayer substrate in which the pads and the like are formed on the substrate 1 and on the back side of the substrate 1, a multilayer substrate, in which a plurality of wiring layers or the like are formed, may also be used. Furthermore, although, in the first exemplary embodiment, the first pad serves as a ground pad to which a ground voltage is supplied, and the second pad 4 serves as a power supply pad to which a power supply voltage is supplied, the first pad 3 may alternatively serve as a power supply pad and the second pad 4 may alternatively serve as a ground pad.

Further, it is noted that Applicant's intent is to encompass equivalents of all claim elements, even if amended later during prosecution.

What is claimed is:

1. A semiconductor device, comprising:
an insulating substrate;
a semiconductor chip mounted on the insulating substrate;
a first pad formed on the insulating substrate, for applying a first power supply potential to the semiconductor chip;
a first bonding wire directly connected between the first pad and the semiconductor chip;
a second pad formed on the insulating substrate, for applying a second power supply voltage to the semiconductor chip;
a second bonding wire directly connected between the second pad and the semiconductor chip;
a dielectric film formed between the first pad and the second pad to form a capacitance together with the first pad and the second pad; and
a plurality of solder balls formed on a back side of the insulating substrate, for respectively and electrically connecting the first pad and the second pad to an external device via respective through holes formed in the insulating substrate.

2. The semiconductor device according to claim 1, further comprising:
an electrode formed on one of the first pad and the second pad, and the dielectric film.

3. The semiconductor device according to claim 1, wherein:
the dielectric film covers the first pad and does not cover the second pad; and
an electrode is formed on the second pad and the dielectric film.

4. The semiconductor device according to claim 1, wherein the insulating substrate comprises a multilayer substrate which includes a plurality of wiring layers therein.

5. The semiconductor device according to claim 1, further comprising:
an electrode connected to the first pad and disposed above the second pad.

6. The semiconductor device according to claim 1, further comprising:
a plurality of the first pads;
a plurality of the second pads; and
a plurality of third pads connected to respective signal terminals formed on the semiconductor chip,
wherein the plurality of third pads are disposed at a periphery of the insulating substrate and one of the first pads and the second pads are disposed at an inner periphery of the insulating substrate.

7. A semiconductor device, comprising:
a substrate having a first surface and a second surface opposing to said first surface;
a semiconductor chip mounted on said first surface of said substrate;
a first pad formed on said first surface of said substrate to electrically connect to a first terminal of said semiconductor chip, said first pad being circularly arranged to surround said semiconductor chip;
a second pad formed on said second surface of said substrate to electrically connect to a second terminal of said semiconductor chip, said second pad being circularly arranged to surround said first pad; and
a decoupling capacitor formed on said first surface and including said first and second pads serving as electrodes of the decoupling capacitor.

8. The semiconductor device as claimed in claim 7, further comprising:
a dielectric film formed between said first and second pads to constitute said decoupling capacitor.

9. The semiconductor device as claimed in claim 8, wherein said dielectric film is formed on said first pad.

10. The semiconductor device as claimed in claim 9, further comprising:
a conductive layer formed on said first pad via said dielectric film and electrically connected to said second pad.

11. The semiconductor device as claimed in claim 7, further comprising:
a first group of solder balls formed on said second surface of said substrate and connected to said first pad through respective via holes; and
a second group of solder balls formed on said second surface of said substrate and connected to said second pad through respective via holes.

12. The semiconductor device as claimed in claim 7, further comprising:
a plurality of third pads formed on said first surface of said substrate to electrically connect to a plurality of third terminals of said semiconductor chip, said first pad being circularly arranged to surround said second pad.

13. The semiconductor device as claimed in claim 7, wherein said second pad includes a plurality of parts independently provided.

14. The semiconductor device as claimed in claim 7, further comprising:
a mold resin sealing said semiconductor chip, said decoupling capacitor, and said first and second pads.
